(19) United States
(12) Patent Application Publication
(10) Pub. No.: US 2012/0065920 A1
(43) Pub. Date: Mar. 15, 2012

(54) EVALUATION METHOD, EVALUATION APPARATUS, AND SIMULATION METHOD OF SEMICONDUCTOR DEVICE

(75) Inventors: Toshiharu NAGUMO, Kanagawa (JP); Kiyoshi TAKEUCHI, Kanagawa (JP)

(73) Assignee: RENESAS ELECTRONICS CORPORATION, Kanagawa (JP)

(21) Appl. No.: 13/222,019

(22) Filed: Aug. 31, 2011

(30) Foreign Application Priority Data
Sep. 10, 2010 (JP) 2010-203419

(51) Int. Cl. G06F 19/00; G01R 31/02

(52) U.S. Cl. 702/117; 324/762.01

(57) ABSTRACT

An evaluation method of a semiconductor device according to an aspect of the present invention includes MISFETs including a gate insulating film, the evaluation method including measuring an RTN of a plurality of MISFETs, and extracting at least two parameters selected from a position of a trap in the gate insulating film, an energy of the trap, an RTN time constant, and an RTN amplitude based on a measurement result of the RTN, and obtaining a correlation between these at least two parameters.

### CROSS-REFERENCE τ0 RELATED APPLICATIONS

This application is based upon and claims the benefit of priority from Japanese patent application No. 2010-203419, filed on Sep. 10, 2010, the disclosure of which is incorporated herein in its entirety by reference.

### BACKGROUND

The present invention relates to an evaluation method, an evaluation apparatus, and a simulation method of a semiconductor device. In particular, the present invention relates to an evaluation method, an evaluation apparatus, and a simulation method of a semiconductor device including an MISFET (Metal-Insulator-Semiconductor Field-Effect Transistor).

In MISFETs, electrical charges are captured by traps present in the gate insulating film or by interface states present at the interface between the gate insulating film and the semiconductor substrate, causing characteristics of the FETs such as a threshold voltage and an electrical current to fluctuate. As a technique for evaluating such traps and interface states in the insulating film, a technique based on measurement of a threshold voltage shift, a charge pumping method, and the like have been known. Further, it is possible to estimate the density of the interface state and the energy distribution by comparing a measured capacitance-voltage (C-V) characteristic with a theoretically-calculated ideal C-V characteristic.

Japanese Unexamined Patent Application Publication No. 3-132052 discloses an interface trap evaluation method using light-irradiation. Specifically, after an electrical charge is captured in the interface trap of an MISFET, the MISFET is irradiated with monochromatic light having an energy E for a time t. As a result, the captured electrical charge is excited and thereby vanished. The trap level density and the energy distribution of the trap level density are obtained based on the time constant of the threshold voltage change of the MISFET and its dependence on the energy E in this state.

Japanese Unexamined Patent Application Publication No. 2003-7791 discloses an electrical charge trap density evaluation method in which an electrical charge is injected into a trap while changing the pulse time t of a pulse voltage applied to the gate. Then, the shift amount ΔVth of the threshold voltage Vth between before and after the charge injection is obtained. Further, the dependence of the time derivative dVth/dt of the shift amount ΔVth on the pulse time is obtained. Next, the base rate of the shift amount ΔVth is obtained by extrapolating this pulse time dependence to the pulse time t=0. Then, the electrical charge trap density is calculated by substituting this base rate into a theoretical formula.

R. Degraeve et al. (“Trap spectroscopy by change injection and sensing (TSICS): A quantitative electrical technique for studying defects in dielectric stacks”, International Electron Device Meeting, pp. 775-778, 2008) discloses a method for evaluating a trap distribution in an insulating film in which a threshold voltage shift amount is measured while changing the gate voltage value and its pulse time t. Further, the position in the film thickness direction and the energy of the trap, into which an electrical charge is injected, are calculated for each combination of a gate voltage value and a pulse time t by theoretically calculating the relation between the tunnel barrier distance from the insulating film/semiconductor interface to the trap and the tunneling time. By comparing these calculated values with the above-described measurement result of the threshold voltage shift amount, the trap density distribution over the position in the film thickness direction and the energy in the insulating film can be obtained. Note that the “film thickness direction” means the direction perpendicular to the gate insulating film/semiconductor interface.

In the charge pumping method, a pulse voltage is applied to the gate so that an electrical charge is captured in a trap or an interface state present in the insulating film, and then an electrical charge that is emitted again when no gate voltage is applied is detected as a substrate current. In this way, the interface level density and the trap density are obtained. Further, the energy distributions for the interface level and the trap are obtained by carrying out the measurement while changing the applied pulse voltage to various values.

Incidentally, a phenomenon in which characteristic values of an MISFET such as a threshold voltage and a current change over time in a discrete manner due to repeated capture/emission of an electrical charge by a single trap present in a gate insulating film has been known. This phenomenon is called “RTN (Random Telegraph Noise)”. For an MISFET having a small size (gate length L× gate width W), the effect of each trap in the gate insulating film is significant. Therefore, the RTN becomes noticeable especially in small MISFETs. Further, the amplitude of characteristic variations caused by the RTN is different from one MISFET to another even when they are manufactured by the same manufacturing method and have the same size. That is, as MITFETs have become smaller, the evaluation of characteristic variations caused by the RTN has become more important.

In each of the above-described C-V measurement, the methods disclosed by Japanese Unexamined Patent Application Nos. 3-132052 and 2003-7791, and R. Degraeve et al., the size of MISFETs is sufficiently large with respect to the trap density and a large number of traps are contained in one component. In such devices, the threshold voltage shift amount for each trap is averaged over a large number of traps. Therefore, the trap density can be measured with moderate accuracy. However, as for devices having a small size, which are often used in recent circuit designing, the number of traps contained in one device is small. Therefore, the threshold voltage shift amount for each trap is not averaged. Therefore, it has been impossible to obtain an accurate trap density for devices having a small size by using the above-mentioned methods. As a result, it has been also impossible to estimate the amplitude distribution of characteristic variations caused by the RTN.

Meanwhile, Zeynep Celik-Butler et al. (“A Method for Locating the Position of Oxide Traps Responsible for Random Telegraph Signals in Sub-micron MOSFETs”, IEEE Transactions on Electron Devices, vol. 47, pp. 646-648, 2000) and Seungwon Yang et al. (“Simultaneous Extraction of Locations and Energies of Two Independent Traps in Gate Oxide From Four-Level Random Telegraph Signal Noise”, Japanese Journal of Applied Physics, vol. 47, No. 4, pp. 2606-2609, 2008) disclose techniques to derive a trap position in the film thickness direction and a trap energy in the gate insulating film. According to their technique, the trap position in the film thickness direction and the trap energy can be derived based on the dependence of the ratio between an RTN capture time constant and an RTN emission time constant on the gate voltage. Note that the “RTN capture time constant” means an average time from when a trap emits an electrical charge to when the trap captures an electrical charge again. Further, the “RTN emission time constant” means an average time from when a trap captures an electrical charge to when the trap emits the electrical charge. Japanese Unexamined Patent Application Publication No. 8-288348 discloses a method that makes it possible to derive the position of a trap on a plane parallel to the gate insulating film/semiconductor interface.

Further, Japanese Unexamined Patent Application Publication No. 2006-252648 discloses a testing method for detecting a retention failure in a DRAM circuit that is caused because of the variations of the data retention time due to the RTN.

### SUMMARY

However, the present inventors have found the following problem. In the methods disclosed by Zeynep Celik-Butler et al. and Seungwon Yang et al., there is a possibility that only a trap(s) of the MISFET on which the measurement was carried out has, by chance, the measured parameters relating to the RTN such as a trap position, a trap energy, an RTN time constant, and an RTN amplitude. In other words, any statistically-meaningful test result cannot be obtained for the RTN. Therefore, it has been impossible to accurately implement the quality determination of insulating films relating to the RTN, the pass/fail determination of the manufacturing process, circuit designing, and so on.

A first aspect of the present invention is an evaluation method of a semiconductor device including an MISFET including a gate insulating film, the evaluation method including:

measuring an RTN of a plurality of MISFETs; and

extracting at least two parameters selected from a position of a trap in the gate insulating film, an energy of the trap, an RTN time constant, and an RTN amplitude based on a measurement result of the RTN, and obtaining a correlation between these at least two parameters.

Another aspect of the present invention is an evaluation apparatus of a semiconductor device including an MISFET including a gate insulating film, the evaluation apparatus including:

an RTN measurement unit that measures an RTN of an MISFET; and

a parameter extraction unit that extracts at least two parameters selected from a position of a trap in the gate insulating film, an energy of the trap, an RTN time constant, and an RTN amplitude based on a measurement result of the RTN, and obtains a correlation between these at least two parameters.

Another aspect of the present invention is a simulation method of a semiconductor device including an MISFET including a gate insulating film, the simulation method including:

measuring an RTN of a plurality of MISFETs;

extracting at least two parameters selected from a position of a trap in the gate insulating film, an energy of the trap, an RTN time constant, and an RTN amplitude based on a measurement result of the RTN, and obtaining a probability density distribution function for each of the at least two parameters in such a manner that a correlation between the at least two parameters is taken into account in the probability density distribution function; and

generating a simulated-RTN in the MISFET to be simulated by using the probability density distribution function.

According to an aspect of the present invention, at least two parameters selected from a position of a trap in the gate insulating film, an energy of the trap, an RTN time constant, and an RTN amplitude are extracted based on a measurement result of the RTN, and then a correlation between the at least two parameters is obtained. As a result, it is possible to accurately implement the quality determination of insulating films relating to the RTN, the pass/fail determination of the manufacturing process, circuit designing, and so on.

### BRIEF DESCRIPTION OF THE DRAWINGS

The above and other aspects, advantages and features will be more apparent from the following description of certain embodiments taken in conjunction with the accompanying drawings, in which:

FIG. 1 is a flowchart of an evaluation method of a semiconductor device according to an embodiment of the present invention;

FIG. 2 is a schematic diagram of an evaluation method of a semiconductor device according to an embodiment of the present invention;

FIG. 3 is a configuration diagram of a semiconductor evaluation apparatus according to another embodiment of the present invention;

FIG. 4 is a flowchart of a simulation of a frequency distribution of maximum RTN amplitudes by using a semiconductor device simulation method according to another embodiment of the present invention;

FIG. 5 is a flowchart of a simulation of a circuit malfunction probability due to RTNs by using a semiconductor device simulation method according to another embodiment of the present invention;

FIG. 6 is a flowchart of a section for determining an RTN characteristic of an FET in a semiconductor device simulation method according to another embodiment of the present invention;

FIG. 7A is a measurement result of a drain current Id of an FET caused by an RTN contributed by one trap in a first example;

FIG. 7B is an example of a histogram of a drain current Id of an FET caused by an RTN contributed by one trap in a first example;

FIG. 8A is a measurement result of a drain current Id of an FET caused by an RTN contributed by a plurality of traps in a first example;

FIG. 8B is an example of a histogram of a drain current Id of an FET caused by an RTN contributed by a plurality of traps in a first example;

FIG. 9A shows an example of the dependence of extraction results of a capture time constant τc and an emission time constant τe of an RTN caused by a type-I trap on the gate voltage, and definitions of parameters Vg0 and τ0 in a first example;

FIG. 9B is an example of a semilogarithmic plot of a time constant ratio τc/τe of an RTN caused by a type-I trap on the gate voltage in a first example;

FIG. 10A is a schematic diagram of a band diagram of an MIS structure including a type-I trap within the insulating film in a first example (when a gate voltage is applied);

FIG. 10B is a schematic diagram of a band diagram of an MIS structure including a type-I trap within the insulating film in a first example (when no gate voltage is applied);

FIG. 11A shows an example of the dependence of extraction results of a capture time constant τc and an emission time constant τe of an RTN caused by a type-II trap on the gate voltage in a first example;

FIG. 11B is an example of a semilogarithmic plot of a time constant ratio τs/τe of an RTN caused by a type-II trap on the gate voltage in a first example;

FIG. 12A is a schematic diagram of a band diagram of an MIS structure including a type-II trap within the insulating film in a first example (when a gate voltage is applied);

FIG. 12B is a schematic diagram of a band diagram of an MIS structure including a type-II trap within the insulating film in a first example (when no gate voltage is applied);

FIG. 13 is a histogram showing a distribution of normalized trap positions XT/TOX in a first example;

FIG. 14 is a histogram showing a distribution of trap energies ET0-EC in a first example;

FIG. 15 is a correlation plot in which extraction results of normalized trap positions XT/TOX and trap energies ET0-EC are mapped in a first example;

FIG. 16 is a correlation plot in which extraction results of normalized trap positions XT/TOX and time constants τ0 are mapped in a first example;

FIG. 17 is a correlation plot in which extraction results of normalized trap positions XT/TOX and RTN amplitudes ΔVth are mapped in a first example;

FIG. 18 is a correlation plot in which extraction results of time constants Δ0 and RTN amplitudes ΔVth are mapped in a first example;

FIG. 19 shows a comparison between a simulation result of a malfunction probability in an SRAM cell read operation and an experiment result of the malfunction probability;

FIG. 20 is correlation plots in each of which extraction results of normalized trap positions XT/TOX and RTN amplitudes ΔVth are mapped for an FET manufactured by a different manufacturing method in a first example; and

FIG. 21 is a schematic diagram of a cumulative probability distribution of maximum RTN amplitudes.

### DETAILED DESCRIPTION

Embodiments of the present invention are explained hereinafter in detail with reference to the drawings. However, the present invention is not limited to the embodiments shown below. Further, the following descriptions and the drawings are partially simplified as appropriate for clarifying the explanation.

### First Embodiment

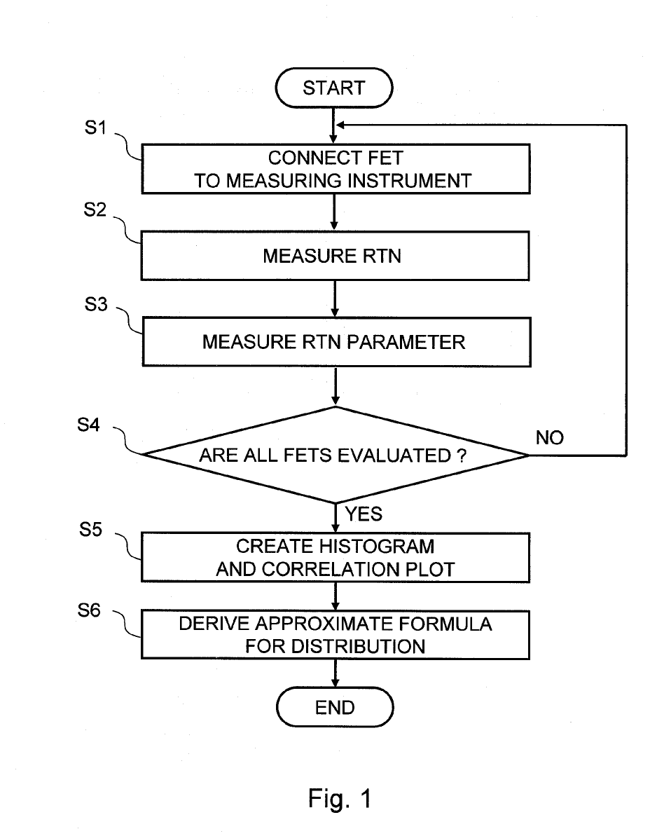

Firstly, an evaluation method of a semiconductor device according to an embodiment of the present invention is explained. FIG. 1 is a flowchart of an evaluation method of a semiconductor device according to this embodiment. In the evaluating procedure according to this embodiment, firstly, an MISFET (hereinafter, simply called “FET”) to be measured is connected to a measuring instrument (step S1).

Next, an RTN (Random Telegraph Noise) of the FET is measured (step S2). For example, a predetermined bias voltage is applied to each electrode of the source/drain/gate/substrate of the FET, and the drain current is measured at predetermined time intervals (at a predetermined sampling rate). Alternatively, a predetermined bias current is applied to the drain electrode of the FET, and the voltage between the gate and the source is measured at predetermined time intervals. In the RTN measurement, it is necessary to carry out measurement under a plurality of measurement conditions by appropriately changing the applied bias voltage, the temperature, and/or the like.

Next, parameters relating to the RTN (hereinafter called “RTN parameters”) such as an RTN amplitude, RTN time constants (capture time constant and emission time constant), a trap position in the gate insulating film, and a trap energy are extracted based on the RTN measurement result of the FET obtained in the step S2 (step S3).

When the drain current is measured in the step S2, a discrete variation width ΔId of the drain current Id can be used as the RTN amplitude value to be extracted in the step S3. Further, a value ΔId/Id obtained by dividing ΔId by Id, a value ΔVth (=ΔId/gm) obtained by dividing ΔId by a mutual conductance gm, and the like can be also used. Note that the mutual conductance gm may be measured separately from the drain current. Meanwhile, when the voltage between the gate and the source is measured in the step S2, a discrete variation width of the gate-source voltage can be used as the RTN amplitude value to be extracted in the step S3. In the extraction of the trap position in the step S3, at least a position coordinate in the film thickness direction among the three directions of the three-dimensional space is extracted. Further, either or both of the positional coordinates on the two-dimensional plane parallel to the insulating film/semiconductor substrate interface may be also extracted. As for the technique for extracting the trap position and the trap energy used in the step S3, the technique based on the dependence of the ratio τs/τe between a capture time constant τc and an emission time constant τe on the gate voltage, which is disclosed by Zeynep Celik-Butler et al. and Seungwon Yang et al., can be used (which is explained later in a more detailed manner).

Next, it is determined whether all the FETs to be measured have been evaluated or not (step S4). If the evaluation of all the FETs have not been completed (No at step S4), the process returns to the step S1 and the above-described steps S1 to S3 are repeated for the next FET to be measured. If the evaluation of all the FETs have been completed (Yes at step S4), a histogram of a trap position distribution, a trap energy distribution, an RTN time constant distribution, and/or an RTN amplitude distribution, or a correlation plot obtained by mapping the distribution of traps on a plane such as a trap-position-vs.-RTN-amplitude plane is created based on the trap positions and the trap energies extracted in the step S4 (step S5).

Next, formulas each approximating the distribution of one of the obtained RTN parameters are derived (step S6). Note that the process flow does not necessarily have to include both of the steps S5 and S6.

Further, the RTN measurement in the step S2 may be carried out for each FET one by one, or may be carried out simultaneously for two or more FETs in parallel. Further, the RTN measurement of all the FETs to be measured may be carried out first (step S2), and then the RTN parameters may be extracted (step S3). Further, the histogram or the correlation plot in the step 5 may be created in advance, and then every time one FET is evaluated, the histogram or the correlation plot may be updated.

As for the FETs to be measured, FETs having a small size (gate length L× gate width W) are used. In particular, it is desirable to use FETs having the shortest gate length and the narrowest gate width that can be manufactured on a stable basis. Further, for each type of several types of FETs having different gate lengths or gate widths, a large number of FETs may be prepared and measured. To obtain a correlation between different RTN parameters, it is necessary to measure at least ten FETs that are manufactured by the same manufacturing process and have the same size. Further, it is desirable to measure at least 1000 FETs having the same size in order to statistically evaluate the distribution of each RTN parameter with accuracy.

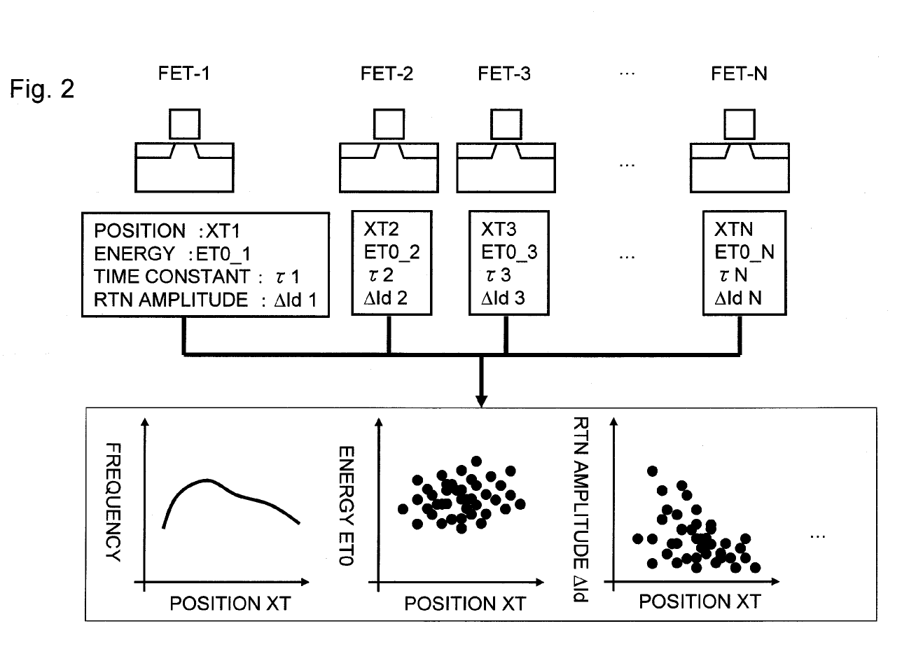

FIG. 2 is a schematic diagram of an evaluation method of a semiconductor device according to this embodiment. The first FET (FET-1) has a trap that causes an RTN within the gate insulating film. A set of parameters consisting of a trap position XT1, an energy ET0_1, a time constant τ1, and an RTN amplitude ΔId1 of that trap is extracted based on RTN measurement on this FET-1. Note that the energy ET0 is a trap energy ET in a state where no electric field is applied to the gate insulating film. Further, the time constant t includes a capture time constant τc and an emission time constant τe. Further, the capture time constant τC and the emission time constant to vary according to the gate voltage. Therefore, it is preferable to use the time constant τ0 (=τc=τe) that is obtained under the condition that the time constant ratio τc/τe becomes one (τc/τe=1) as the time constant to be extracted.

Likewise, RTNs of N FETs are measured. By doing so, a set of parameters consisting of a trap position XT2, an energy ET0_2, a time constant τ2, and an RTN amplitude ΔId2 of the trap in the FET-2, a set of parameters consisting of a trap position XT3, an energy ET0_3, a time constant τ3, and an RTN amplitude ΔId3 of the trap in the FET-3, . . . , and a set of parameters consisting of a trap position XTN, an energy ET0_N, a time constant TN, and an RTN amplitude ΔIdN of the trap in the FET-N are extracted. By combining the extraction results of these N traps, it is possible to obtain the distribution of the positions XT, the distribution of the energies ET0, the distribution of the time constants τ, and the distribution of the amplitudes ΔId.

Further, for example, it is also possible to map pairs of a position XT and an energy ET0 on a plane on which the horizontal axis represents the position XT and the vertical axis represents the energy ET0 and thereby to determine the degree of the correlation between the distributions of the position XT and the energy ET0. Likewise, it is also possible to determine the degree of the correlations between the position XY and the amplitude ΔId, between the position XY and the time constant τ, between the energy ET0 and the amplitude ΔId, between the energy ET0 and the time constant τ, and between the amplitude ΔId and the time constant t by carrying out the mapping of these pairs.

Note that the number of traps that cause an RTN in one FET is not limited to one. That is, a plurality of traps may be present in one FET. In an FET in which a plurality of traps cause RTNs, its current value fluctuates between three or more discrete values. In the FET like this, it is desirable to extract the position, the energy, the time constant, and the amplitude for every trap in the FET. However, it is difficult to carve out the individual contribution of each trap from RTN measurement data in which the current value fluctuates between a large number of discrete values. Therefore, only one or some of the plurality of traps may be selected and the parameters may be extracted for the selected trap(s). Meanwhile, there are FETs in which no distinct RTN can be observed. Needless to say, the extraction of the trap position and the like is not carried out for such FETs.

The RTN time constant is widely different from one electrical charge trap to another. That is, the RTN time constants are distributed over a number of digits at least from the order of micro seconds to the order of several hours. To deal with these widely-different RTN time constants, the RTN measurement should be, ideally, carried out at as high sampling rate as possible and for as long time as possible. However, this is often unrealistic because the data amount becomes extremely larger and thereby exceeds the maximum memory capacity of the measuring instrument, and/or the load of the extraction process becomes excessively larger. Therefore, it is preferable to combine short-time measurement at a high sampling rate with long-time measurement at a low sampling rate. In this way, RTNs can be effectively dealt with over a wide time-constant range. Note that it is desirable that the maximum sampling rate is at least ten times higher than the minimum sampling rate in each measurement.

According to this embodiment, in addition to evaluating each of a plurality of types of RTN parameters that can be extracted from RTN measurement results as an individual distribution of each parameter, it is also possible to grasp a correlation between different RTN parameters. In particular, it is possible to grasp a correlation between different RTN parameters in a fine FET, which cannot be predicted from measurement of FETs having a large size. For example, a trap distribution may be mapped on a trap-position-vs.-trap-energy plane, a trap-position-vs.-RTN-amplitude plane, and so on. In this way, it is possible to examine the degree of the correlation between these distributions. Further, by describing each of the statistic distributions by a distribution function, it is possible to express their mutual relevancies by using distribution functions into which the mutual relevancies are incorporated as numerical formulas. The statistically-meaningful distribution evaluation like this can be used for the pass/fail determination of a manufacturing process, circuit designing, and so on.

### Second Embodiment

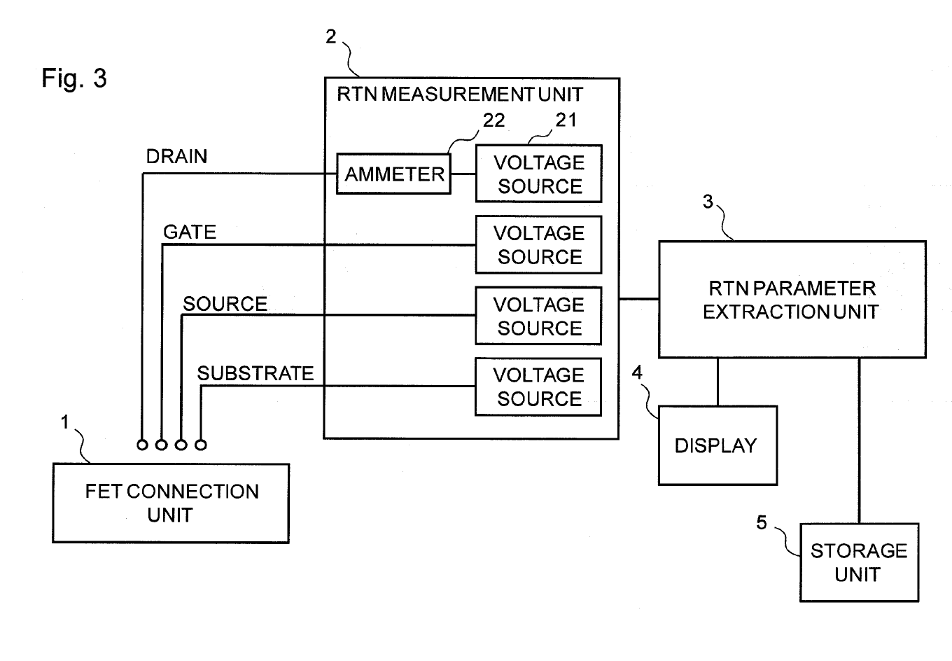

Next, an evaluation apparatus of a semiconductor device according to another embodiment of the present invention is explained. FIG. 3 is a configuration diagram of an evaluation apparatus according to this embodiment. The evaluation apparatus according to this embodiment includes an FET connection unit 1, an RTN measurement unit 2, an RTN parameter extraction unit 3, a display unit 4, and a storage unit 5.

An example of the FET connection unit 1 is a prober equipped with a movable stage. An FET to be measured is mounted on the FET connection unit 1. As shown in FIG. 3, the FET connection unit 1 has a mechanism for connecting the four electrodes corresponding to the drain/gate/source/substrate of the FET to respective measurement terminals of the RTN measurement unit 2. Further, the FET connection unit 1 also has a mechanism for switching the FET to be measured from one FET to another.

The RTN measurement unit 2 includes four terminals to be connected to the drain/gate/source/substrate, respectively, of the FET mounted on the FET connection unit 1, four voltage sources 21 connected to the respective terminals, and an ammeter connected in series to the drain terminal. A predetermined bias voltage is applied to each terminal by a respective one of the voltage sources, and a current value is measured by the ammeter at a predetermined sampling rate. The measurement is carried out while changing the bias voltages applied to the respective terminals to various values.

The RTN parameter extraction unit 3, which may be an electronic computer or the like, extracts an RTN amplitude, a capture time constant, and an emission time constant based on measurement data obtained by the RTN measurement unit 2, and also extracts the position and the energy of a trap present in the gate insulating film. As for the technique for extracting the trap position and the trap energy, the technique based on the dependence of the ratio τs/τe between a capture time constant τc and an emission time constant τe on the gate voltage, which is disclosed by Zeynep Celik-Butler et al. and Seungwon Yang et al., can be used.

When the measurement of one FET to be measured is finished, the FET connection unit 1 connects the next FET to be measured to the RTN measurement unit 2 by using the switching mechanism. Then, the RTN measurement and the RTN parameter extraction are carried out. Similarly, a series of above-described operations is repeated for a number of FETs and the RTN parameters are thereby extracted for each of the number of FETs. Note that the evaluation apparatus may be configured in such a manner that two or more FETs can be simultaneously measured in parallel.

An example of the display unit 4 is a display or a printer. The display unit 4 displays a histogram of each RTN parameter distribution and/or a correlation plot between different RTN parameters. Alternatively, the display unit 4 displays formulas approximating the distributions and/or values of parameters contained included in the formulas.

An example of the storage unit 5 is a built-in memory of an electronic computer, a hard disk drive, a removable storage medium, or the like. The storage unit 5 stores a list of extracted RTN parameters, drawing data of histograms and correlation plots, approximate formulas of distributions and parameter values of the formulas, and so on.

The configuration of the RTN measurement unit 2 shown in FIG. 3 is an example of configuration for measuring a drain current. In the case of measuring a current at a terminal other than the drain terminal, an ammeter is connected to the terminal to be measured. Further, when the voltage between the gate and the source or the like is measured while applying predetermined bias currents to the FET, current sources are connected to the terminals to which the bias currents are applied and a voltmeter is connected between the terminals to be measured.

By using the evaluation apparatus according to this embodiment of the present invention, in addition to evaluating each of a plurality of types of RTN parameters that can be extracted from RTN measurement results as an individual distribution of each parameter, it is also possible to grasp mutual relevancies. That is, similar advantageous effects to those of the first embodiment can be achieved.

### Third Embodiment

Next, a simulation method of a semiconductor device according to another embodiment of the present invention is explained. In this simulation method, results that are obtained by the evaluation method of a semiconductor device according to the first embodiment of the present invention are applied to the simulation. The simulation like this can be implemented, for example, by using a SPICE (Simulation Program with Integrated Circuit Emphasis) on a computer.

Firstly, an approximate formula is obtained for each of statistical distributions of RTN parameters extracted from RTN measurement results for a large number of FETs. Each of these approximate formulas is defined as a probability density distribution function corresponding to a respective one of the distributions. Next, a Monte Carlo simulation, in which RTNs are generated in accordance with these probability density distribution functions in a probabilistic manner, is performed. In this manner, it is possible to reproduce an occurring frequency of characteristic variations caused by RTNs and/or an RTN amplitude distribution under a predetermined bias condition in the simulation. Further, by applying this Monte Carlo simulation in which RTNs are generated in a probabilistic manner to a simulation for calculating an operating margin and/or a delay time of a circuit, it is possible to estimate the malfunction probability of the circuit caused by RTNs.

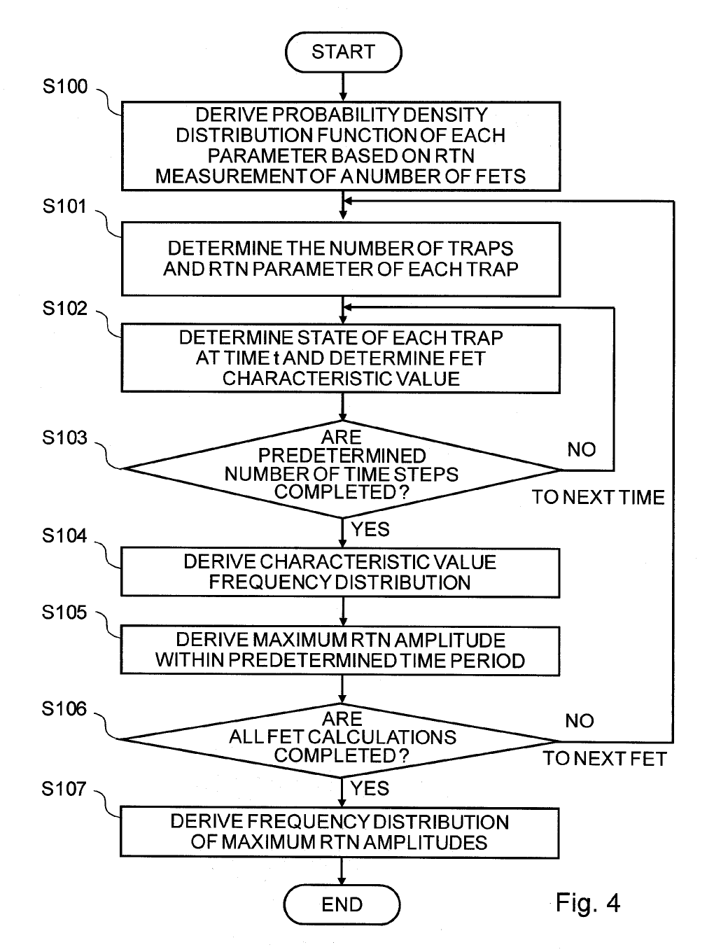

FIG. 4 is a flowchart of a simulation of a frequency distribution of maximum RTN amplitudes by using a semiconductor device simulation method according to this embodiment. Note that the “maximum RTN amplitude” means the peak-to-peak variation width of a characteristic value in which the occurrence of superposition of RTN amplitudes due to contributions from a plurality of traps is taken into account. Firstly, a probability density distribution function is derived for each RTN parameter (such as a trap position, a trap energy, a time constant, and an RTN amplitude) based on RTN measurement for a large number of FETs (step S100).

Next, the number of traps contained in one FET and RTN parameters (such as a trap position, a trap energy, a time constant, and an RTN amplitude) for each of the traps are determined in a probabilistic manner in accordance with the probability density distribution functions derived in the step S100 (step S101).

Next, a characteristic value(s) of that FET at a time t is determined in a probabilistic manner based on the time constant and the amplitude determined in the step S101 (step S102).

Next, it is determined whether the calculation of a predetermined number of time steps is completed or not (step S103). If the calculation is not completed (No at step S103), the time step is advanced by one step. Further, the step S102 is repeated until the calculation of the predetermined number of time steps is completed. If the calculation of the predetermined number of time steps is completed (Yes at step S103), a frequency distribution of the characteristic values that have occurred during a predetermined time period is derived (step S104).

Next, the maximum RTN amplitude that has occurred in the predetermined time period in that FET is derived (step S105). Next, it is determined whether the simulation of a predetermined number of FETs is completed or not (step S106). If the simulation is not completed (No at step S106), the processes in the steps S101 to S105 are carried out for the next FET. Further, the series of these operations is repeated for all the FETs. If the simulation of all the FETs is completed (Yes at step S106), the maximum RTN amplitudes of all the FETs obtained in the step S105 are summarized and a frequency distribution of the maximum RTN amplitudes is thereby derived (step S107).

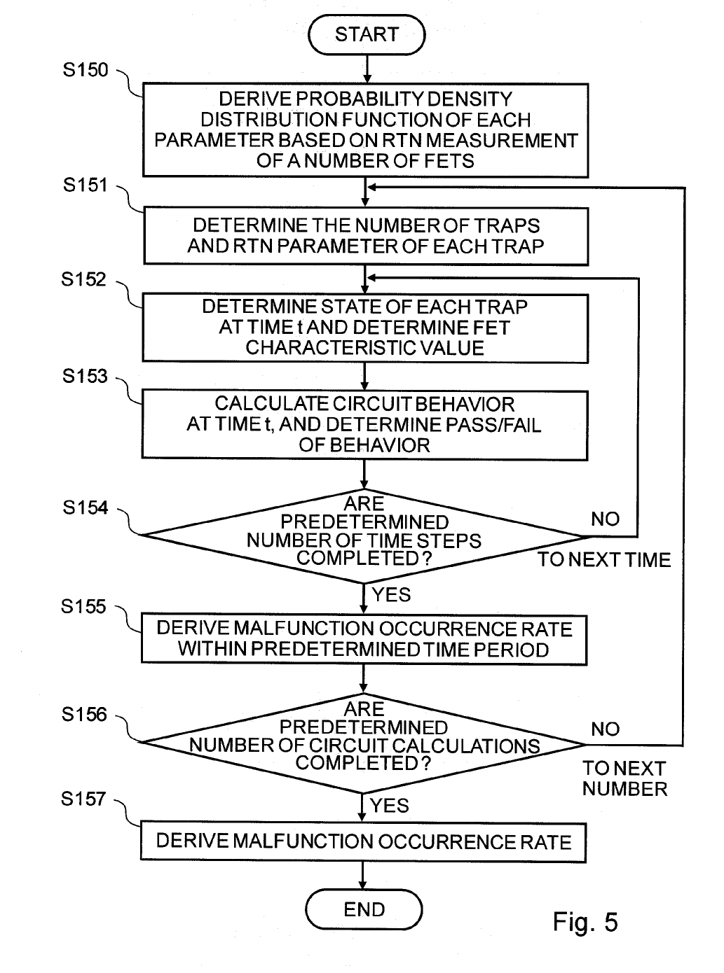

FIG. 5 is a flowchart of a simulation of the probability of a circuit malfunction caused by RTNs using a semiconductor device simulation method according to this embodiment. Firstly, steps S150 to S152 are carried out in a similar manner to the steps S100 to S102 of FIG. 4. Note that the determination of a characteristic value(s) in the steps S151 and S152 in which RTNs are taken into account may be carried out for one FET among the FETs constituting the circuit, or may be carried out for each of two or more FETs.

Next, the behavior of the circuit is calculated by using the characteristic value of the FET at the time t, which is determined in the step S152, and it is thereby determined whether the circuit operates properly or not (step S153).

Next, it is determined whether the calculation of a predetermined number of time steps is completed or not (step S154). If the calculation is not completed (No at step S154), the time step is advanced by one step. Further, the steps S152 and S153 are repeated until the calculation of the predetermined number of time steps is completed. If the calculation of the predetermined number of time steps is completed (Yes at step S154), a probability that the circuit malfunctions within a predetermined time period is derived, or a decision whether the circuit has malfunctioned at least once during a predetermined time period or not is made (step S155).

Next, it is determined whether the simulation of a predetermined number of circuit operations is completed or not (step S156). If the simulation is not completed (No at step S156), the processes in the steps S101 to S105 are repeated. If the simulation of the predetermined number of circuit behaviors is completed (Yes at step S156), the malfunction probabilities of all the circuits or the occurrences/non-occurrences of malfunctions are summarized, and a malfunction occurrence probability in a large number of circuits is thereby derived (step S157).

By appropriately setting the operating voltage of a circuit, input signal timings to the circuit, the sizes of FETs constituting the circuit, and/or the like based on the result of this malfunction occurrence probability simulation in such a manner that the malfunction occurrence probability of the circuit becomes lower than a predetermined value, it is possible to produce a semiconductor integrated circuit having a low malfunction occurrence probability.

The reproduction accuracy/prediction accuracy of these simulations can be improved by incorporating a correlation(s) between the distributions of at least two parameters selected from the trap position, the trap energy, the time constant, and the RTN amplitude derived by measurement of a large number of FETs into the simulations. For example, this process may be implemented in the following manner.

Firstly, a probability density distribution function f1(n) describing a distribution of n traps contained in an FET that cause an RTN is determined. Next, a probability density distribution function f2(XT) describing a distribution of trap positions XT within the gate insulating film is determined. Next, a probability density distribution function f3(ET0; XT) describing a distribution of trap energies ET0 is determined. Note that f3(ET0; XT) is a function including XT as a parameter, and the distribution shape of ET0 changes according to the value of XT. Next, a probability density distribution function f4(τ; XT, ET0) describing a distribution of time constants τ is determined. Note that f4(τ; XT, ET0) is a function containing XT and ET0 as parameters, and the distribution shape of τchanges according to the values of XT and ET0. Next, a probability density distribution function f5(ΔId; XT, ET0, τ) describing a distribution of amplitudes ΔId is determined. Note that f5(ΔId; XT, ET0, τ) is a function containing XT, ET0 and τ as parameters, and the distribution shape of ΔId changes according to the values of XT, ET0 and τ. Each of the above-described functions f2 to f5 is determined so that the function reflects a mutual relation between distributions derived by measurement of a large number of FETs.

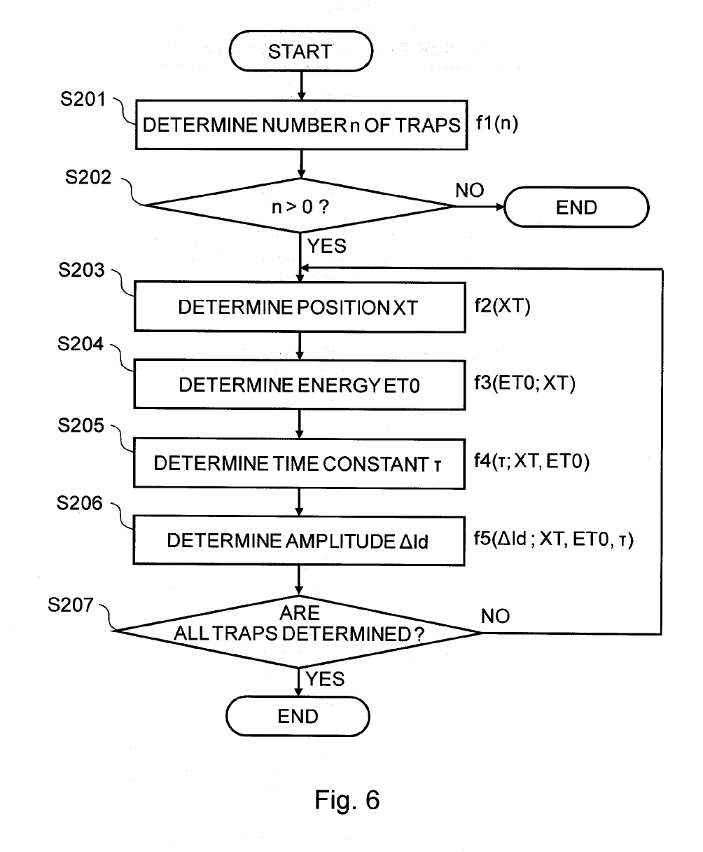

By using each of the above-described functions f2 to f5, RTN parameters of FETs are determined in a probabilistic manner in a Monte Carlo simulation. FIG. 6 is a flowchart of a section for determining an RTN parameter(s) of an FET in the step S101 of FIG. 5 or in the step S151 of FIG. 6.

Firstly, a random number is generated and the number n of traps contained in an FET is determined in accordance with the function f1(n) (step S201).

Next, it is determined whether the number n of traps is greater than zero (n>0) or not (step S202). If the number n of traps is zero (n=0) (No at step S202), no RTN occurs in that FET and the process is finished. If the number n is greater than zero (n>0) (Yes at step S202), the process proceeds to a next step in which a position, an energy, a time constant, and an amplitude are determined for each trap in order starting from the first trap.

Specifically, firstly, a random number is generated and the position XT of a trap is determined in accordance with the function f2(XT) (step S203). Next, a random number is generated and the energy ET0 of the trap is determined in accordance with the position XT and the function f3(ET0; XT) (step S204). Next, a random number is generated and the time constant t of the trap is determined in accordance with the position XT, the energy ET0, and the function f4(τ; XT, ET0) (step S205). Next, a random number is generated and the amplitude ΔId is determined in accordance with the position XT, the energy ET0, the time constant t and the function f5(ΔId; XT, ET0, t) (step S206).

Next, it is determined whether or not the determination of the position and other parameters is completed for all of n traps (step S207). If the determination for all of n traps is not completed (No at step S207), the process returns to the step S203 and the operations in the steps S203 to S206 are carried out for the next trap. Similarly, the operations in the steps S203 to S206 are carried out for all of n traps. If the operations in the steps S203 to S206 are completed for all of n traps (Yes at step S207), the process is finished.

Note that the order of dependence relations between those probability density distribution functions is not limited to the above-described example. Further, it is not always necessary to incorporate the correlations of all of the four parameters, i.e., the trap position, the trap energy, the time constant, and the RTN amplitude into the simulation. Further, correlations with parameters other than these four parameters may be also incorporated into the simulation.

When FETs having different gate lengths L and different gate widths W are to be simulated, RTN amplitude distribution functions corresponding to the respective sizes may be used. Note that each of the RTN amplitude distribution functions is obtained based on RTN measurement of a large number of FETs. Note that, in general, the average number of traps contained in one FET is roughly in proportion to the size (L×W) of the FET. In contrast to this, the average value of RTN amplitudes caused by one trap is roughly in inverse proportion to the size of the FET. Therefore, it is possible to simulate an RTN characteristic of an FET having a certain size for which no measurement was carried out by using its size ratio to an FET for which actual measurement was carried out. Specifically, for the number of traps, a probability density distribution function can be obtained by multiplying an already-obtained probability density distribution function by the size ratio. Further, for the RTN amplitude distribution, a probability density distribution function can be obtained by multiplying an already-obtained probability density distribution function by the inverse of the size ratio.

### First Example

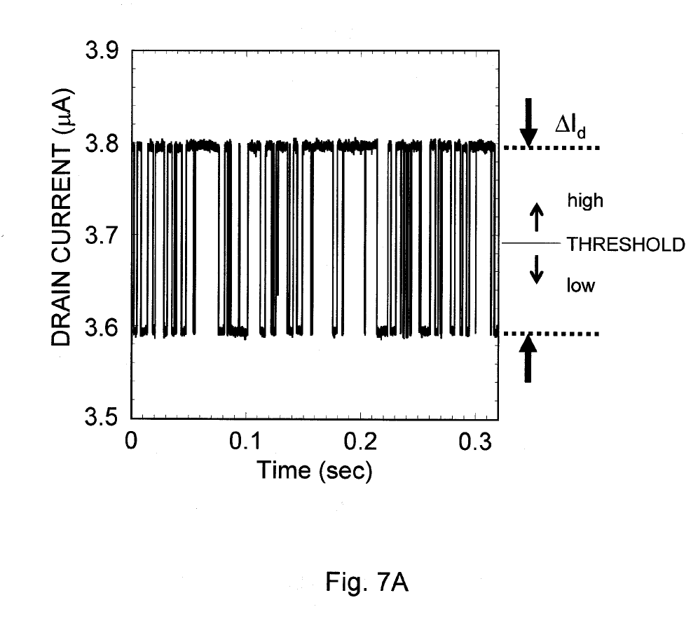

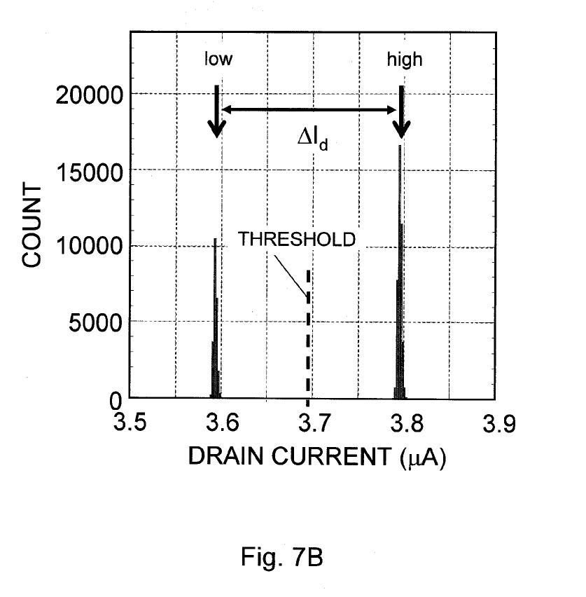

An example of an evaluation method of a semiconductor device according to an embodiment of the present invention is explained. FIG. 7A is an example of a measurement result of a drain current Id of an FET in a state where a constant gate voltage Vg and a drain voltage Vd are applied to the FET. In this FET, RTNs occur and the current value fluctuates between two discrete values over time. From this measurement data, an RTN amplitude ΔVth, a capture time constant τc, and an emission time constant τe are extracted in the following manner.

Firstly, the two discrete values of the current Id are extracted and the variation width ΔId between the two discrete values is obtained. FIG. 7B shows a distribution of the current values Id as a histogram. For example, the variation width ΔId can be extracted by detecting the positions of peaks (indicated by arrows in the figure) in this histogram. Then, the RTN amplitude ΔVth=ΔId/gm is calculated by using a mutual conductance gm=∂Id/∂Vg, which is separately obtained based on a measurement result of the drain current Id and the gate voltage Vg.

Further, the center value between the two extracted current values is defined as a threshold. Further, the state where the current value Id is higher than the threshold is defined as a high state and the state where the current value Id is lower than the threshold is defined as a low state. Then, it is determined whether the FET is in the high state or the low state at each time point of the measurement. Note that the high state corresponds to a state where the trap has emitted an electrical charge and the threshold voltage of the FET is thereby lowered, while the low state corresponds to a state where the trap has captured an electrical charge and the threshold voltage of the FET is thereby raised. When an electrical charge is captured, the FET changes from a high state to a low state, whereas when an electrical charge is emitted, the FET changes from a low state to a high state. The duration of each of the high state and the low state as well as the number of transitions from the high state to the low state are obtained. Then, the capture time constant τc and the emission time constant to are calculated by using the following formulas.

τc=(sum total of high-state durations)/(number of transitions) (1a)

τe=(sum total of low-state durations)/(number of transitions) (1b)

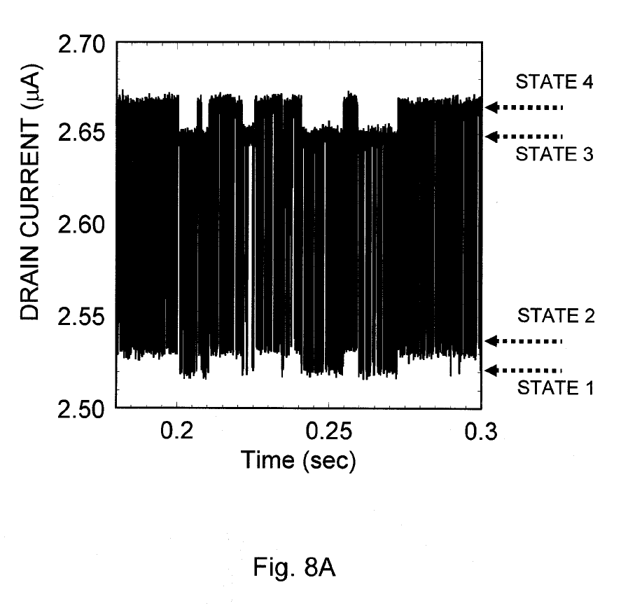

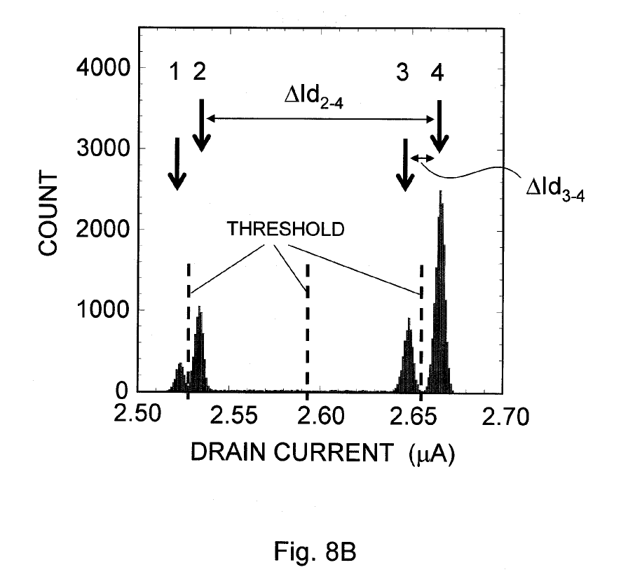

FIG. 8A is an example of a measurement result of the drain current Id of another FET. In this FET, RTNs are caused in such a manner that the current value fluctuates among four discrete values. FIG. 8B is a histogram of the drain current values Id. Similarly to the previous example, four discrete values of the drain current Id can be detected by detecting peak positions in this histogram. As shown in FIG. 8B, the four states in which the drain current Id takes on respective discrete values are defined as states 1 to 4. It is believed that, in this FET, each of two traps individually captures/emits an electrical charge, thus resulting in the occurrence of the four states. The transitions between the states 1 and 3 and between the states 2 and 4 are caused by the electrical charge capture/emission by the first trap, while the transitions between the states 1 and 2 and between the states 3 and 4 are caused by the electrical charge capture/emission by the second trap.

In RTNs that are caused by a plurality of traps, each trap is located in a different position, and has a different energy, a time constant, and an RTN amplitude. To extract the time constant of each of the plurality of traps, it is necessary to correctly determine the number of transitions from one state to another for each combination of two states among a number of states. Therefore, such RTNs require complicated processes in comparison to the case where there are only two states caused by only one trap. For RTNs caused by contributions from a plurality of traps, the following first to third processes can be used.

In the first process, FETs having a plurality of traps are eliminated from the trap evaluation, and only FETs having only one trap and for which the process is thereby easy are evaluated.

In the second process, only a trap(s) that causes the largest amplitude among a plurality of traps is evaluated. In the example shown in FIGS. 8A and 8B, only the first trap is evaluated. The center value between the current values corresponding to the states 2 and 3 is determined, and the states 1 and 2 are collectively defined as a low state while the states 3 and 4 are collectively defined as a high state. In this way, the time constant of the first trap can be calculated in a similar manner to that of the example shown in FIGS. 7A and 7B.

In the third process, the duration of each state and the number of transitions from one state to another are obtained, and the time constant and the amplitude for all of the plurality of traps are evaluated. This process can be carried out in the following manner.

A first threshold is set at the center value between the peak at the lowest drain current Id and the peak at the second lowest drain current Id. Further, second and third thresholds are set at the center value between the second and the third peaks and at the center value between the third and the fourth peaks respectively. Then, the state where the current value Id is lower than the first threshold is defined as a state 1 at each time point of the sampling. Similarly, the state where the current value Id is between the first and second thresholds is defined as a state 2. The state where the current value Id is between the second and third thresholds is defined as a state 3. Further, the state where the current value Id is larger than the third threshold is defined as a state 4.

The number of transitions from the state 4 to the state 3, from the state 4 to the state 2, from the state 3 to the state 1, and the state 2 to the state 1 as well as the duration of each of the four states are obtained.

The time constant of the first trap can be calculated from Formulas (1a) and (1b) by substituting “the sum total of the durations of the states 4 and 3” into “sum total of high-state durations”, “the sum total of the durations of the states 2 and 1” into “sum total of low-state durations”, and “the sum of the number of transitions from the state 4 to the state 2 and the number of transitions from the state 3 to the state 1” into “number of transitions”.

The time constant of the second trap can be also calculated from Formulas (1a) and (1b) by substituting “the sum total of the durations of the states 4 and 2” into “sum total of high-state durations”, “the sum total of the durations of the states 3 and 1” into “sum total of low-state durations”, and “the sum of the number of transitions from the state 4 to the state 3 and the number of transitions from the state 2 to the state 1” into “number of transitions”.

However, there are cases in which it is difficult to determine, for example, whether both the transitions between the state 1 and 3 and the transitions between the states 2 and 4 are caused by the electrical charge capture/emission by the same trap or not. Therefore, the following method can be also used.

Firstly, similarly to the above-described method, the duration of each of the four states is obtained. In the example shown in FIGS. 8A and 8B, the state 4 has the longest duration in total among the four states. Therefore, the state 4 is defined as a reference state, and each of the number of transitions from the state 4 to the state 3, the number of transitions from the state 4 to the state 2, and the number of transitions from the state 4 to the state 1 is obtained. Then, by defining the state 4 as the high state, the state 2 as the low sate, and the number of transitions from the state 4 to the state 2 as the number of transitions, the time constant of the first trap can be calculated from Formulas (1a) and (1b). Further, by defining the state 4 as the high state, the state 3 as the low sate, and the number of transitions from the state 4 to the state 3 as the number of transitions, the time constant of the second trap can be calculated from Formulas (1a) and (1b). Note that the FETs rarely change from the state 4 to the state 1. Therefore, the transitions from the state 4 to the state 1 are assumed not to be the transitions caused by the electrical charge capture/emission by only one trap and thereby eliminated from the calculation.

Further, the variation width ΔId2-4 between the current values in the states 4 and 2 and the variation width ΔId3-4 between the current values in the states 4 and 3 are obtained. Then, by dividing each of these variation widths by the mutual conductance gm, the RTN amplitude ΔVth is calculated for each of the first and second traps.

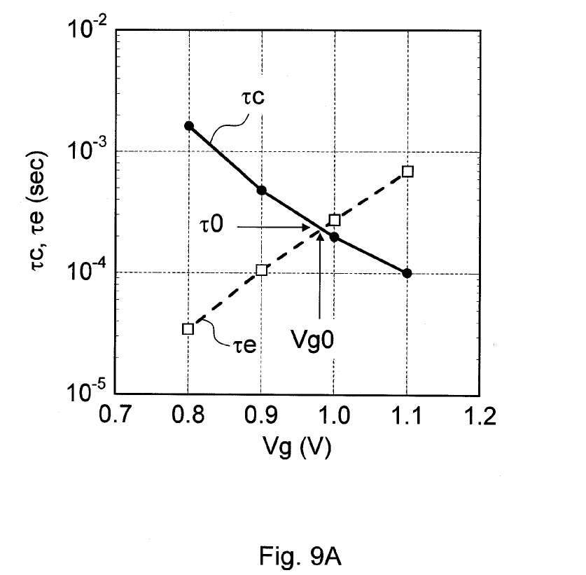

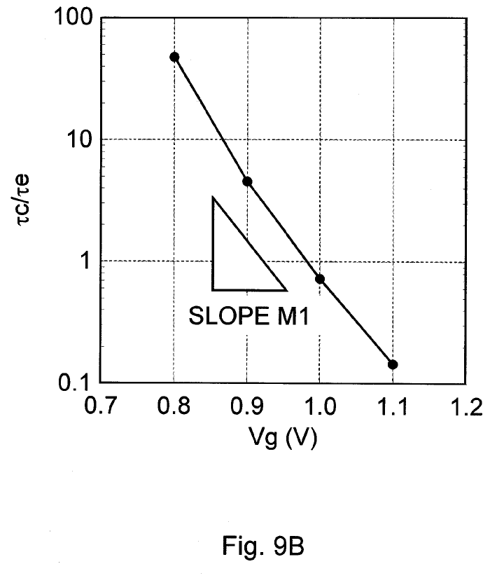

The extraction of a time constant based on a measurement result of the drain current Id at a certain gate voltage Vg like the one described above is carried out for various gate voltages Vg. FIG. 9A is a graph obtained by plotting extraction results of the capture time constant τc and the emission time constant τe for the same FET that were obtained by measuring the drain current Id while changing the gate voltage Vg. Each of the capture time constant τc and the emission time constant τe changes according to the gate voltage Vg. Note that the gate voltage Vg at which the capture time constant τc and the emission time constant τe becomes equal to each other is defined as “Vg0”. Further, the value of the capture time constant τc and the emission time constant τe at the gate voltage Vg0 is defined as “τ0”. The gate voltage Vg0 is obtained by interpolation. When the capture time constant τc and the emission time constant τe do not cross each other in the measurement range of the gate voltage Vg, the gate voltage Vg0 and the time constant τ0 are obtained by extrapolation.

FIG. 9B is a semilogarithmic plot showing the dependence of the time constant ratio τs/τe on the gate voltage. The time constant ratio τs/τe has a rectilinear relation with the gate voltage Vg in the semilogarithmic graph. Most of the traps exhibit a downward slope like the one shown in FIG. 9B. That is, the time constant ratio τs/τe decreases with the increases of the gate voltage Vg. In this specification, such traps are called “type-I traps”. It is believed that in a type-I trap, electrical charge capture/emission occurs between the trap and the semiconductor substrate.

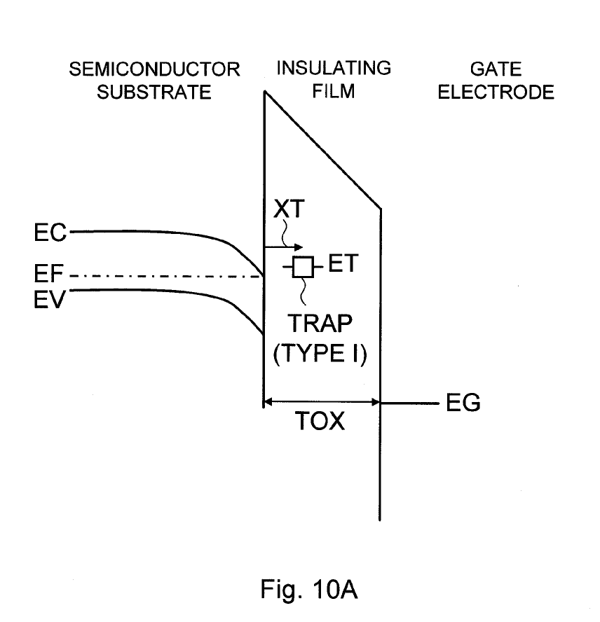

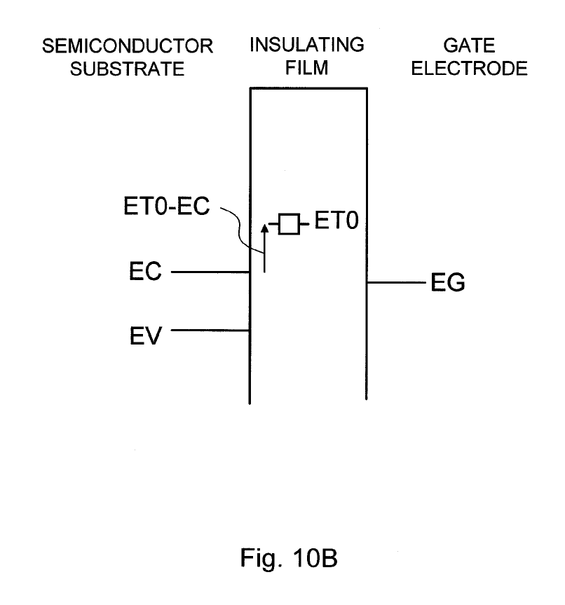

FIG. 10A schematically shows an energy band diagram of an MIS structure including a type-I trap within the insulating film. Assume that a trap having an energy ET is present in an insulating film having a thickness TOX at a position that is away from the semiconductor substrate/insulating film interface by a distance XT. In the semiconductor substrate shown in FIG. 10A, an energy EC at a conduction band edge, an energy EV at a valence band edge, and a Fermi level EF are shown. In the gate electrode shown in FIG. 10A, the work function EG of the gate electrode is shown. As the gate voltage Vg changes, the electric field applied to the gate insulating film changes. Further, a trap energy Et also changes according to that change. The change of the time constant ratio τs/τe according to the gate voltage Vg corresponds to the change of “ET-EF”. In a strongly-inverted state, Formula (2) shown below is satisfied between the slope M1 of the straight line shown in FIG. 9B and the distance XT. In the formula, k is Boltzmann constant; T is absolute temperature; and q is elementary charge.

XT/TOX=−(kT/q)×ln M1 (2)

That is, the trap position XT/TOX, i.e., the trap position normalized by the insulating film thickness TOX can be extracted based on the straight-line slope M1 in FIG. 9B. If the insulating film thickness value TOX is known by using another method or the like, the trap position value XT itself can be also obtained.

The gate voltage Vg0 roughly corresponds to the gate voltage Vg in the state where the trap energy ET is equal to the Fermi level EF (ET−EF=0). As shown in FIG. 10B, when the trap energy ET in a state where no electric field is applied to the gate insulating film is defined as “ET0”, the trap energy ET0 is roughly calculated from Formula (3) shown below.

ET0−EF=(Vg0+V0)/(XT/TOX) (3)

In the formula, V0=−VFB−Φs; VFB is flat band voltage; and Φs is surface potential of the semiconductor substrate in the strongly-inverted state. In the strongly-inverted state, the Fermi level EF at the semiconductor substrate/insulating film interface becomes roughly equal to the energy EC when the FET is an N-type FET, whereas the Fermi level EF becomes roughly equal to the energy EV when the FET is a P-type FET. Therefore, the above-shown Formula (3) can be expressed as Formulas (3a) and (3b) shown below for the N-type FET and the P-type FET respectively.

ET0−EC=(Vg0+V0)/(XT/TOX); (N-type FET) (3a)

ET0−EV=(Vg0+V0)/(XT/TOX); (P-type FET) (3b)

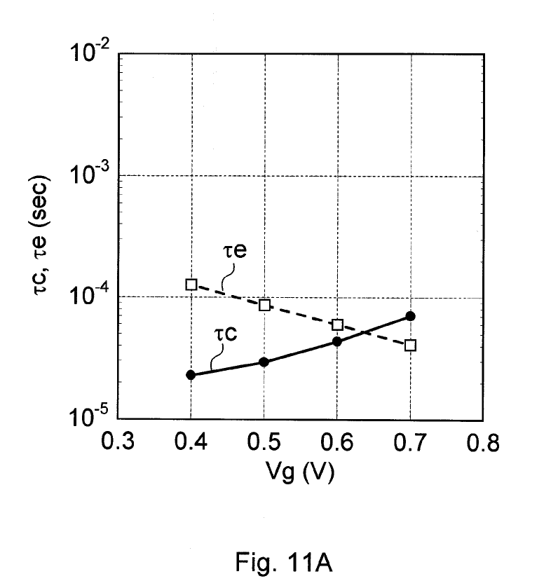

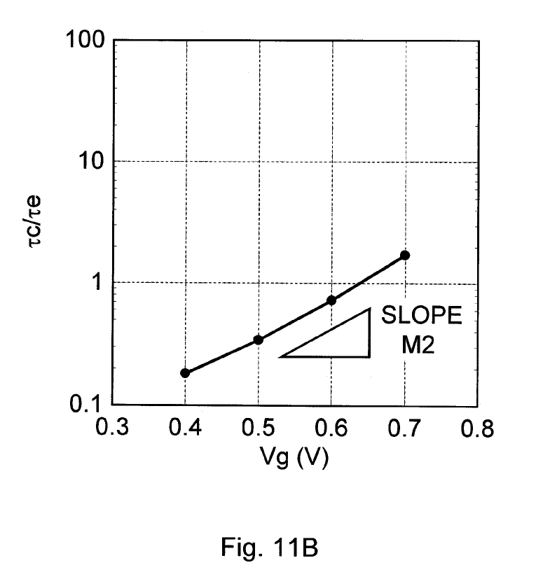

FIG. 11A is a graph obtained by plotting extraction results of the dependence of the capture time constant τc and the emission time constant to on the gate voltage for an FET that is different from the FET of FIG. 9. Further, FIG. 11B a semilogarithmic plot showing the dependence of the time constant ratio τs/τe on the gate voltage. As shown in the graphs, there are traps having such a slope that the time constant ratio τs/τe increases with the increases of the gate voltage Vg. Such traps are called “type-II traps”. It is believed that in a type-II trap, electrical charge capture/emission occurs between the trap and the gate electrode.

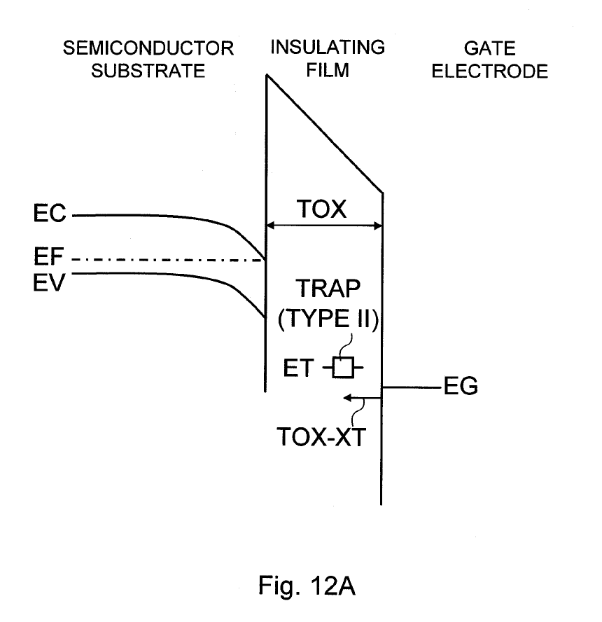

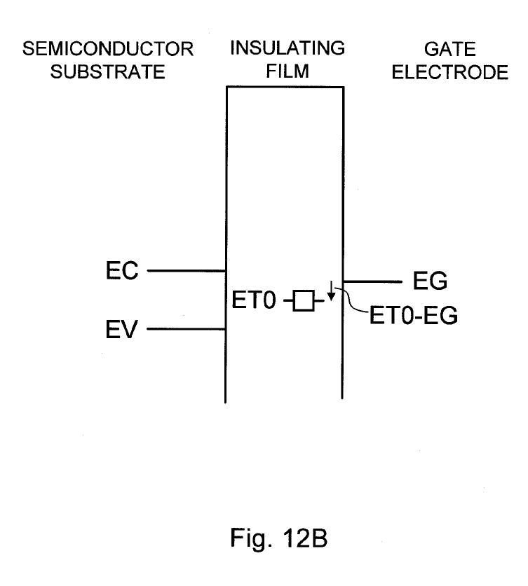

FIG. 12A schematically shows an energy band diagram of an MIS structure including a type-II trap within the insulating film. In the semiconductor substrate shown in FIG. 12A, an energy EC at a conduction band edge, an energy EV at a valence band edge, and a Fermi level EF are shown. In the gate electrode shown in FIG. 12A, the work function EG of the gate electrode is shown. In the type-II trap, the change of the time constant ratio τs/τe according to the gate voltage Vg corresponds to the change of “ET-EG”. Similarly to Formula (2), Formula (4) shown below is satisfied between the slope M2 of the straight line shown in FIG. 11B and the distance TOX−XT.

(TOX−XT)/TOX=(kT/q)×ln M2 (4)

Therefore, the trap position XT can be extracted based on Formula (4). Similarly to FIG. 10B, FIG. 12B shows a schematic band diagram in a state where no electric field is applied to the gate insulating film. The energy ET0 of the type-II trap can be roughly calculated from Formula (5) shown below.

ET0−EG=(Vg0+V0)/[TOX−XT)/TOX] (5)

Note that Formulas (2), (3), (3a), (3b), (4) and (5) are derived on the assumption that the semiconductor substrate is in a strongly-inverted state and the surface potential are unchanged regardless of the change of the gate voltage Vg. The surface potential varies in a weakly-inverted state. Further, even in the strongly-inverted state, the surface potential slightly varies. Therefore, for more accurate calculation, it is desirable to use formulas according to Seungwon Yang et al. or the like in which these effects are taken into account. That is, the trap position XT and the trap energy ET0 calculated from Formulas (2), (3a), (3b), (4) and (5) are approximated values. In this example, approximated values of the trap position XT/TOX at which RTNs occur and the trap energy ET0 for an N-type FET are extracted by using Formulas (2), (3a), (4) and (5) on the assumption that V0=0.02V.

RTN measurement based on the drain current Id was carried out on a large number of fine n-type FETs that have the same size (gate length=54 nm and gate width W=126 nm) and were manufactured by the same manufacturing process. For each of the FETs to be measured, the measurement was carried out for combinations of a plurality of sampling rates ranging from 10,000 samplings/sec to 1,000,000 samplings/sec. Further, for each measurement, the number of samplings was 64,000 regardless of its sampling rate (i.e., the duration of the measurement changes in proportion to the sampling rate). In the measurement, the drain voltage Vd was fixed at 0.05 V, and the gate voltage Vg was changed from 0.4 V to 1.2 V in increments of 0.1 V. Based on measurement results of the large number of FETs, the above-described series of operations were carried out for about 50 traps that cause RTNs and the above-mentioned four RTN parameters consisting of the trap position XT/TOX, the trap energy ET0-EC, the time constant τ0, and the RTN amplitude ΔVth were extracted.

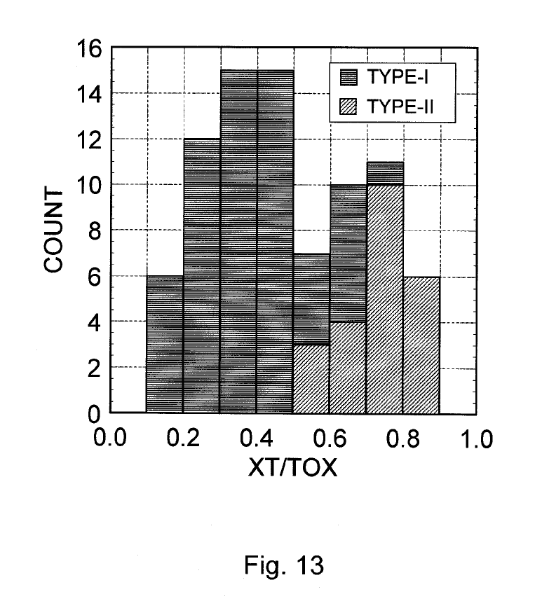

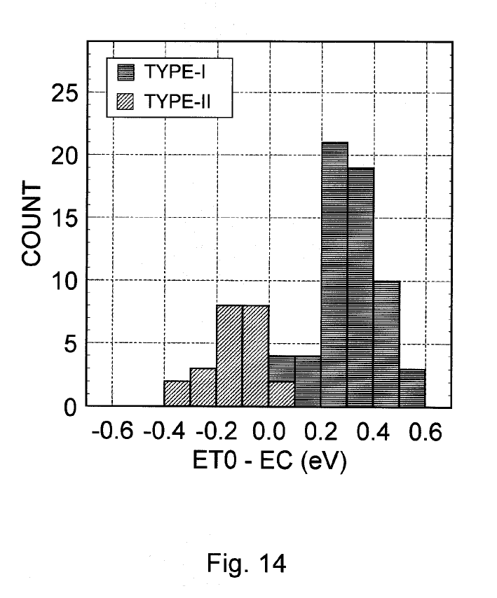

FIG. 13 is a histogram of trap positions XT/TOX. FIG. 14 is a histogram of trap energies ET0-EC. In each of the histograms, traps having types I and II are collectively shown. By creating a histogram, a distribution of traps can be visually grasped. Similarly, histograms can be also created for the time constant and the RTN amplitude.

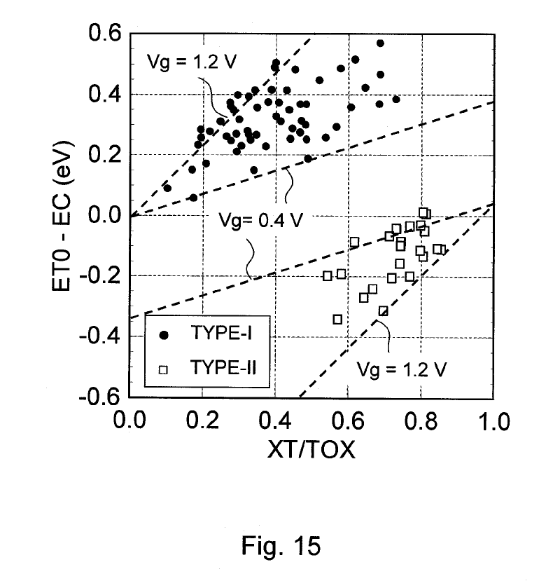

FIG. 15 is a correlation plot in which a distribution of traps is mapped on a plane on which the horizontal axis represents the position XT/TOX and the vertical axis represents the energy ET0-EC. Dotted lines in the figure represent isoelectric lines at the lower-limit and the upper-limit of the gate voltage Vg used in the measurement. Under the measurement condition of this example, only the traps located within the range defined between these two isoelectric lines and traps located slightly outside this range can be extracted.

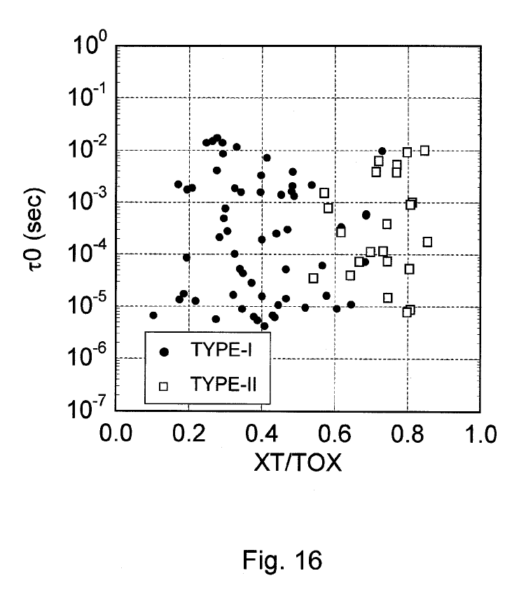

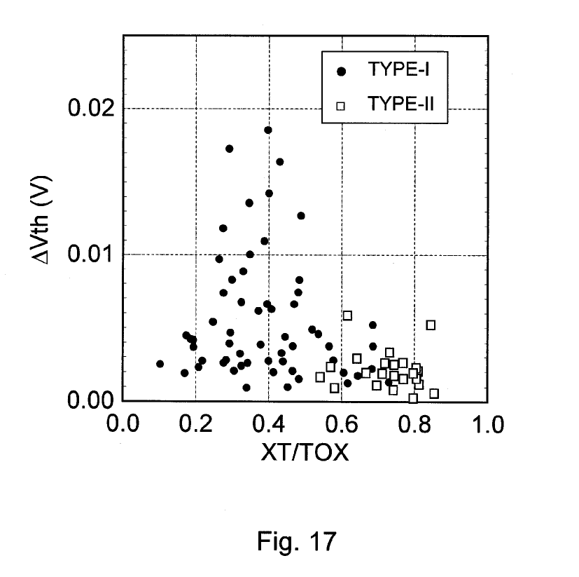

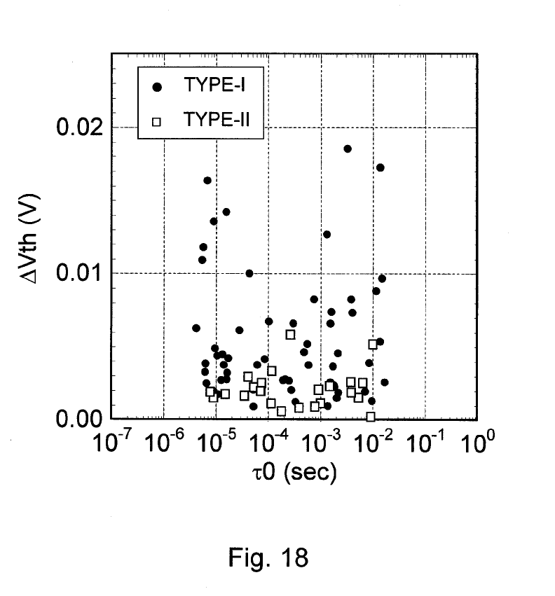

Further, FIG. 16 is a correlation plot in which a distribution of traps is mapped on a plane on which the horizontal axis represents the position XT/TOX and the vertical axis represents the time constant τ0. FIG. 17 is a correlation plot in which a distribution of traps is mapped on a plane on which the horizontal axis represents the position XT/TOX and the vertical axis represents the RTN amplitude ΔVth. By performing these mappings, it is possible to recognize mutual relevancies among the trap position, the trap energy, the time constant, and the RTN amplitude. For example, as can be seen from FIG. 16, there is no obvious relevancy between the time constant τ0 and the trap position XT/TOX. Further, as can be seen from FIG. 17, traps having a large RTN amplitude are mostly distributed on the side closer to the semiconductor substrate with respect to the position XT/TOX=0.5. FIG. 18 is a correlation plot in which a distribution of traps is mapped on a plane on which the horizontal axis represents the time constant τ0 and the vertical axis represents the RTN amplitude ΔVth. As can be seen from FIG. 18, there is no relevancy between the time constant and the RTN amplitude.

Approximate formulas approximating the distributions of the above-mentioned trap position XT/TOX, the trap energy ET0-EC, the time constant τ0, and the RTN amplitude ΔVth, and correlations among these RTN parameters were obtained. In a simulation of a read operation of an SRAM cell, these approximate functions were used as probability density distribution functions in order to generate simulated-RTNs in an FET(s) constituting the SRAM cell. In this way, the occurrence probability of malfunctions, i.e., the occurrence probability of events in which a different value from the value stored in the cell is read out was calculated. Further, similar simulations were also performed on the assumption that the trap position XT/TOX, the trap energy ET0-EC, the time constant τ0, and the RTN amplitude ΔVth are independent of each other. That is, simulations using probability density distribution functions that were derived without giving any consideration to the correlations of these parameters were also carried out.

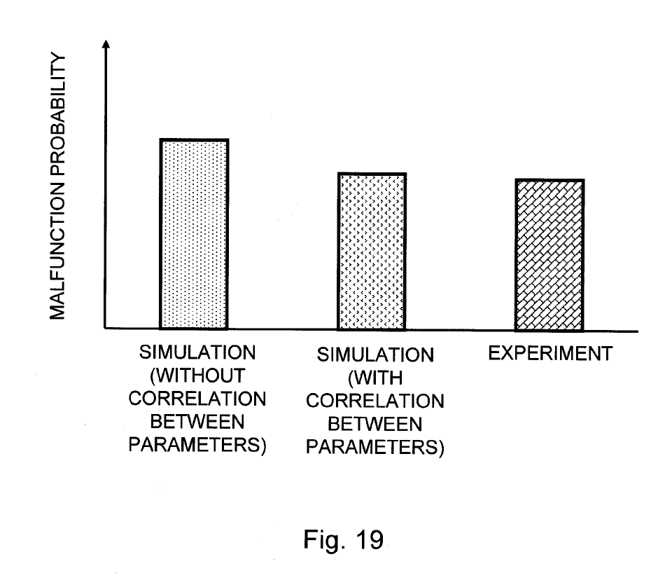

FIG. 19 shows calculation results of the malfunction probability and a measurement result of the malfunction probability. In comparison to the simulation in which the correlations among the parameter distributions are not taken into account, the simulation using probability density distribution functions derived with the consideration given to the correlations provided a more accurately-predicted malfunction probability, i.e., a malfunction probability closer to the actual malfunction probability. Note that although the malfunction probability obtained in the simulation in which the correlations were taken into account is lower than that obtained in the simulation in which the correlations were not taken into account in this example, the magnitude relation between the malfunction probabilities could be reversed in other examples.

As a result of the malfunction probability simulation, when the malfunction probability exceeds a predefined tolerance value (e.g., 1 ppm), the circuit design may be changed, for example, by increasing the gate length or the gate width of the FET(s) constituting the circuit and/or by increasing the operating power supply voltage so that the malfunction probability becomes equal to or lower than the tolerance value. On the other hand, when the malfunction probability is sufficiently lower than the tolerance value, it is possible to reduce the circuit size by reducing the gate length and/or the gate width of the FET(s) constituting the circuit, to reduce the power consumption by lowering the power supply voltage, and/or to increase the operating speed by shifting the timings at which input signals supplied to the circuit forward.

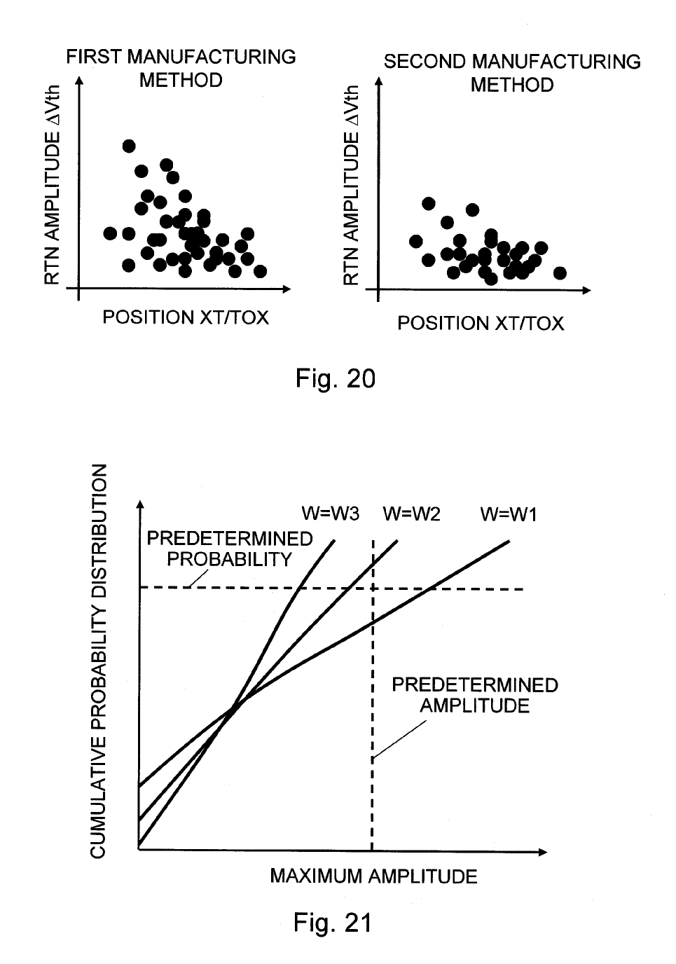

Next, RTN measurement based on the drain current Id was carried out on a large number of FETs manufactured by a first manufacturing method and a large number of FETs manufactured by a second manufacturing method. The first and second manufacturing methods are partially different in their manufacturing processes. Further, by using the measurement results, the trap distributions were evaluated. FIG. 20 shows correlation plots between the trap position XT/TOX and the RTN amplitude ΔVth for the respective manufacturing processes. In comparison to FETs manufactured by the first manufacturing method, FETs manufactured by the second manufacturing method have smaller RTN amplitudes. Therefore, it is expected that using the second manufacturing method can reduce the occurrence probability of malfunctions of the circuit caused by RTNs in comparison to using the first manufacturing method. In this way, by performing feedback on the manufacturing process of FETs based on the evaluation of trap distributions according to an aspect of the present invention, it is possible to improve the reliability of products.

Further, though it is not shown in the figures, the evaluation of trap distributions was also carried out for a first production lot and a second production lot, both of which were manufactured by the same manufacturing process, and it was found out that the first production lot exhibited a smaller distribution of the amplitudes ΔVth than that of the second production lot. In this case, circuits manufactured from the second production lot will have a higher malfunction probability after the shipment in comparison to those manufactured from the first production lot. It is possible to reduce the risk that products that could cause a malfunction could be shipped to the market by imposing a stricter screening condition on the circuits manufactured from the second production lot in a pre-shipment test. On the other hand, it is possible to increase the yield of the circuits manufactured from the first production lot by implementing the pre-shipment test with a less-strict screening condition. As described above, it is also possible to adjust the criterion of the pre-shipment test based on the evaluation result of trap distributions.

### Second Example

For each type of several types of FETs that are manufactured by the same manufacturing process but have different gate widths (W=W1, W2 and W3 (W1<W2<W3)), a large number of FETs are measured and the RTN amplitude distribution is thereby evaluated. Alternatively, a large number of FETs may be measured only for one type of FETs having the same gate width W and probability density distributions of characteristics may be thereby obtained. Then, the amplitude distribution may be simulated for a plurality of types of FETs having different gate widths by using a probability density distribution function for the trap number distribution that is obtained by multiplying the obtained probability density distribution function by the ratio of the gate width W and a probability density distribution function for the RTN amplitude distribution that is obtained by multiplying the obtained probability density distribution function by the inverse of the ratio of the gate width W.

As shown in FIG. 21, a cumulative probability distribution of maximum RTN amplitudes can be obtained for each gate width W. Based on this evaluation, it is possible to determine whether the occurrence probability of a maximum RTN amplitude larger than a predetermine amplitude value is higher than a predetermined probability or not for each gate width W. The “predetermined amplitude value” is, for example, an amplitude value with which the probability that the circuit malfunctions becomes equal to or greater than a certain value. Further, the “predetermined probability” is, for example, a probability that needs to be satisfied to achieve the required yield of the circuit.

For FETs having gate width W=W1, the cumulative probability distribution with which the maximum amplitude becomes equal to or less than the predetermine amplitude value is lower than the predetermined value. That is, the probability that an RTN having an amplitude larger than the predetermined amplitude value is caused is larger than the predetermined probability. In contrast to this, for FETs having gate width W=W2 or gate width W=W3, the probability that an RTN having an amplitude larger than the predetermined amplitude value is caused is lower than the predetermined probability.

Therefore, when circuits are designed using FETs having a gate width W=W1, the probability that the circuits cause malfunctions exceeds the predetermined probability. As a result, the required yield cannot be achieved. In contrast to this, when circuits are designed using FETs having a gate width W=W2 or larger, the required yield can be achieved. Similar evaluations can be also made for a plurality of types of transistors having different gate lengths L. In this manner, it is possible to determine the smallest size of FETs used in circuit designing through the evaluation of RTNs of a large number of FETs.

Although the present invention has been explained with reference to certain embodiments, the present invention is not limited to those embodiments. Various modifications can be made to the configurations and the details of those embodiments by those skilled in the art without departing from the spirit and scope of the present invention.

While the invention has been described in terms of several embodiments, those skilled in the art will recognize that the invention can be practiced with various modifications within the spirit and scope of the appended claims and the invention is not limited to the examples described above.

Further, the scope of the claims is not limited by the embodiments described above.

Furthermore, it is noted that, Applicant's intent is to encompass equivalents of all claim elements, even if amended later during prosecution.

What is claimed is:

1. An evaluation method of a semiconductor device comprising an MISFET comprising a gate insulating film, the evaluation method comprising:
measuring an RTN of a plurality of MISFETs; and
extracting at least two parameters selected from a position of a trap in the gate insulating film, an energy of the trap, an RTN time constant, and an RTN amplitude based on a measurement result of the RTN, and obtaining a correlation between these at least two parameters.

2. The evaluation method of a semiconductor device according to claim 1, wherein
in the RTN measurement, measurement at a first sampling rate and measurement at a second sampling rate are carried out for each of the MISFETs, the second sampling rate being higher than the first sampling rate, and
a measurement time of the measurement at the second sampling rate is shorter than a measurement time of the measurement at the first sampling rate.

3. The evaluation method of a semiconductor device according to claim 1, wherein the plurality of MISFETs include at least ten MISFETs that have a same size and are manufactured by a same manufacturing process.

4. The evaluation method of a semiconductor device according to claim 1, wherein at least one of the trap position and the trap energy is obtained based on dependence of a ratio between a capture time constant and an emission time constant of the trap on a gate voltage.

5. An evaluation apparatus of a semiconductor device comprising an MISFET comprising a gate insulating film, the evaluation apparatus comprising:
an RTN measurement unit that measures an RTN of an MISFET; and
a parameter extraction unit that extracts at least two parameters selected from a position of a trap in the gate insulating film, an energy of the trap, an RTN time constant, and an RTN amplitude based on a measurement result of the RTN, and obtains a correlation between these at least two parameters.

6. The evaluation apparatus of a semiconductor device according to claim 5, wherein
the RTN measurement unit carries out measurement at a first sampling rate and measurement at a second sampling rate for each of the MISFET, the second sampling rate being higher than the first sampling rate, and
a measurement time of the measurement at the second sampling rate is shorter than a measurement time of the measurement at the first sampling rate.

7. The evaluation apparatus of a semiconductor device according to claim 5, wherein the parameter extraction unit obtains at least one of the trap position and the trap energy based on dependence of a ratio between a capture time constant and an emission time constant of the trap on a gate voltage.

8. A simulation method of a semiconductor device comprising an MISFET comprising a gate insulating film, the simulation method comprising:
measuring an RTN of a plurality of MISFETs;
extracting at least two parameters selected from a position of a trap in the gate insulating film, an energy of the trap, an RTN time constant, and an RTN amplitude based on a measurement result of the RTN, and obtaining a probability density distribution function for each of the at least two parameters in such a manner that a correlation between the at least two parameters is taken into account in the probability density distribution function; and
generating a simulated-RTN in the MISFET to be simulated by using the probability density distribution function.

9. The simulation method of a semiconductor device according to claim 8, further comprising estimating a malfunction probability in a circuit comprising an MISFET to be simulated based on the generated simulated-RTN,
wherein a size of the MISFET is determined so that a malfunction probability in the malfunction probability estimation becomes equal to or less than a predetermined value.

10. The simulation method of a semiconductor device according to claim 8, further comprising obtaining a probability density distribution of an estimated RTN amplitude in an MISFET to be simulated based on the generated simulated-RTN,
wherein a size of the MISFET is determined so that a probability that the estimated RTN amplitude exceeds a reference value becomes equal to or less than a predetermined value.

11. The simulation method of a semiconductor device according to claim 8, wherein a Monte Carlo method is used when a simulated-RTN is generated in the MISFET.

12. The simulation method of a semiconductor device according to claim 8, wherein
in the RTN measurement, measurement at a first sampling rate and measurement at a second sampling rate are carried out for each of the MISFETs, the second sampling rate being higher than the first sampling rate, and
a measurement time of the measurement at the second sampling rate is shorter than a measurement time of the measurement at the first sampling rate.

13. The simulation method of a semiconductor device according to claim 8, wherein the plurality of MISFETs include at least ten MISFETs that have a same size and are manufactured by a same manufacturing process.

14. The simulation method of a semiconductor device according to claim 8, wherein at least one of the trap position and the trap energy is obtained based on dependence of a ratio between a capture time constant and an emission time constant of the trap on a gate voltage.

15. The simulation method of a semiconductor device according to claim 8, wherein the plurality of MISFETs and the MISFET to be simulated have a same size.
